(19) United States
(12) Patent Application Publication
(10) Pub. No.: US 2002/0008528 A1
(43) Pub. Date: Jan. 24, 2002

(54) Electronic part inspection method and an electronic part assembly apparatus

(75) Inventors: Koji Sato, Akishima (JP); Yukitaka Sonoda, Higashiyamato (JP)

Correspondence Address: KODA & ANDROLIA, 2029 Century Park East, Suite 3850, Los Angeles, CA, 90067-3024, US

(73) Assignee: KABUSHIKI KAISHA SHINKAWA

(21) Appl. No.: 09/909,023

(22) Filed: Jul. 19, 2001

(30) Foreign Application Priority Data
Jul. 19, 2000 (JP) 2000-219501

(51) Int. Cl. G01R 31/302

(52) U.S. Cl. 324/752

(57) ABSTRACT

By way of utilizing the light transmissivity of a carrier film, the conditions of bonding of leads formed on the carrier film and bonding pads of silicon chips are inspected by an inspection camera based upon the light images of the bonding pads that are transmitted through the carrier film, thus eliminating the need for a complicated inspection process that involves the removal of bonded silicon chips.

### BACKGROUND OF THE INVENTION

1. Field of the Invention

The present invention relates to an electronic part inspection method which is used to inspect the conditions of bonding when solid state devices are bonded to the surface of a carrier film in an electronic part assembly process, and the present invention relates further relates to an electronic part assembly apparatus associated with such a method.

2. Prior Art

As seen from FIG. 6, in a tape carrier system that is a type of semiconductor element assembly system, leads 76 of a specified shape consisting of a conductive layer are formed on the upper surface of a carrier film 2 that is made of a band-form heat-resistant resin film. Then, various types of assembly processes such as the bonding of these leads 76 to the bonding pads (surface electrodes) of silicon chips 78, and the sealing of such elements with a resin, etc. are performed.

In this tape carrier system, as shown in FIG. 7, the tip ends of the leads 76 formed on the surface of the carrier film 2 overhang from the window parts 2a of the carrier film 2. Silicon chips 78 are caused to approach these leads 76 from below, and the leads 76 and bonding pads 80 are thermally fused by applying heat and pressure from above by means of a bonding head containing a heater, or a molten resin material holding a dispersed conductive powder is applied to the interface between the leads and bonding pads and this material is hardened, so that the leads and bonding pads are bonded. In this system, inspection of the product quality following bonding is accomplished by detecting positional deviations between the leads 76 and bonding pads 80 by observation with a camera from above.

However, as the pitch of semiconductor elements has become finer, it has become impossible to ignore the deformation of the leads 76 caused by external forces and heat in the case of this conventional system. In recent years, therefore, a system (flip-chip system) in which leads 76 are formed on the surface of a board 82 consisting of an opaque phenol resin laminated material, etc., and silicon chips 78 which have been inverted are caused to approach the leads 76 from above, and are bonded (as shown in FIG. 8).

In such a flip-chip system, the bonding areas of the leads 76 and bonding pads 80 are located in positions that cannot be seen from the outside. Accordingly, in order to inspect the product quality, it is necessary to strip the bonded silicon chips 78 from the leads 76 on the board 82 and observe the conditions of the bonded surfaces with a microscope. As a result, the inspection process is extremely complicated. A method in which the positional deviation of the bonding pads 80 and leads 76 is inspected by irradiating the assembly with infrared light from the upper surface, causing this infrared light to pass through the silicon chips 78, and detecting light images of the bonding pads 80 and leads 76 in reflected images of this infrared light, has been proposed as described in Japanese Patent Application Laid-Open (Kokai) No. H10270501. However, since this method uses an infrared light apparatus, the method suffers from the problem of increasing the size of the apparatus.

### SUMMARY OF THE INVENTION

Accordingly, the object of the present invention is to provide a method and apparatus that allows the efficient inspection of the conditions of bonding.

The above object is accomplished by a unique method of the present invention for an electronic part inspection method that performs an inspection of a bonding condition between a conductive layer which is formed on an upper surface of a carrier film consisting of a light-transmitting material and bonding pads which are formed on undersurfaces of solid state devices; and in the present invention, the inspection of the bonding condition is performed based upon the light images of the bonding pads that are transmitted through the carrier film.

In this method of the present invention, the light transmissivity of the carrier film is utilized, and the conditions of bonding between the conductive layer formed on the carrier film and the bonding pads of the solid state devices are inspected based upon light images of the bonding pads that are transmitted through the carrier film. Accordingly, a complicated process involving the stripping of bonded silicon chips is unnecessary, and the inspection can be performed with good efficiency.

The above object is accomplished by another unique method of the present for an electronic part inspection method that is comprised of a bonding process for bonding bonding pads formed on undersurfaces of a plurality of solid state devices to a conductive layer formed on an upper surface of a band-form carrier film consisting of a light-transmitting material, and a detection process for detecting conditions of the bonding based upon light images of the bonding pads that are transmitted through the carrier film in a state in which the plurality of solid state devices are held in one set on a surface of the carrier film.

In this method of the present invention, the conditions of bonding are detected based upon light images of the bonding pads that are transmitted through the band-form carrier film in a state in which a plurality of solid state devices are held in a set on the surface of the carrier film. Accordingly, the detection of the bonding condition can be continuously performed without stopping the assembly line, and the inspection process is made even more efficient.

The above object is further accomplished by a unique structure for an electronic part assembly apparatus that comprises a bonding device that bonds bonding pads formed on undersurfaces of a plurality of solid state devices to a conductive layer formed on an upper surface of a band-form carrier film consisting of a light-transmitting material, and a detection device that detects conditions of the bonding based upon light images of the bonding pads that are transmitted through the carrier film in a state in which the plurality of solid state devices are held on a surface of the carrier film.

In the above electronic part assembly apparatus, the bonding device is comprised of an upper member and a lower member that are respectively provided above and below the carrier film, and the assembly apparatus is further provided with a moving stand on which the lower member and the detection device are provided. The lower member and the detection device are selectively positioned, by movement of the moving stand, at a location that faces the upper member; and when the lower member is positioned at a location that faces the upper member, the detection device faces solid state devices following bonding on the carrier film.

In this structure, the lower member and detection device are selectively positioned at a location that faces the upper member by the movement of the moving stand. Accordingly, by placing the detection device at a location that faces the upper member after bonding has been performed by the upper member and lower member, an inspection to ascertain whether or not the bonding process has been performed in a favorable manner is performed without moving the carrier film. Furthermore, the detection device faces the solid state devices following the bonding on the carrier film when the lower member is positioned at a location that faces the upper member. Accordingly, bonding by the upper member and lower member and detection by the detection device can be continuously performed in parallel by feeding the carrier film from a bonding position where the bonding is performed to an inspection position where the detection is performed.

### BRIEF DESCRIPTION OF THE DRAWINGS

FIG. 1 is a front view of the electronic part assembly apparatus according to one embodiment of the present invention;

FIG. 2 is a front view of the moving stand, heater unit and inspection camera;

FIG. 3 is a plan view of the moving stand, heater unit and inspection camera;

FIG. 4 is a sectional view of the moving stand taken along the line 4-4 of FIG. 1;

FIG. 5 is an explanatory diagram of the electrical construction and operation of the embodiment;

FIG. 6 is a plan view of the carrier film;

FIG. 7 is an explanatory diagram of the conventional bonding; and

FIG. 8 illustrates a bonding process that uses a conventional flip-chip system.

### DETAILED DESCRIPTION OF THE INVENTION

A preferred embodiment of the present invention will be described below with reference to the accompanying drawings.

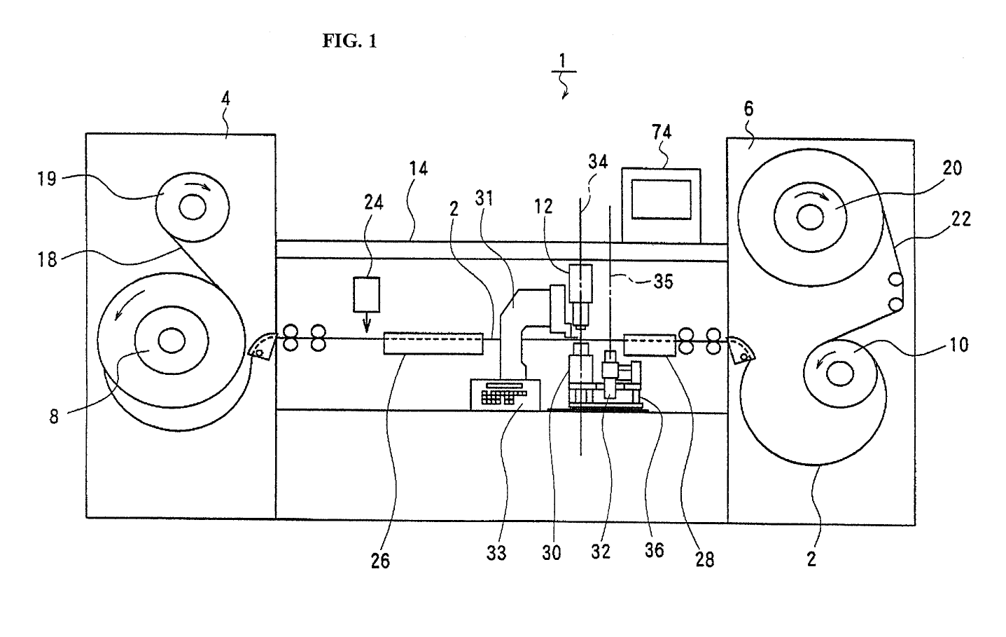

In FIG. 1, the electronic part assembly apparatus 1 of the shown embodiment of the present invention is a die bonder or a die bonding machine. The die bonder is comprised of a loader unit 4 which accommodates an unworked carrier film 2 that is wound on a reel 8, an unloader unit 6 which takes up the worked carrier film 2 on a reel 10, and a bonding unit 14 which is equipped with a bonding head 12 that performs the bonding process.

In addition to the reel 8, the loader unit 4 is equipped also with a spacer reel 19 that takes up a protective tape 18 when the carrier film 2 is unwound. Likewise, in addition to the reel 10, the unloader unit 6 is equipped with a spacer reel 20 which takes up a protective tape 22 when the carrier film 2 is taken up on the reel 10.

In addition to the bonding head 12, a resin-dropping unit 24, drying sections 26 and 28, a heater unit 30 and an inspection camera 32 are installed in the bonding unit 14. Furthermore, a transfer arm 31, that places the silicon chips on the carrier film 2, and an operating panel 33, that operates the transfer arm 31, are disposed in the vicinity of the bonding position 34.

The resin-dropping unit 24 drops a resin material in which a conductive powder is dispersed onto the conductive layer of the carrier film 2. The drying sections 26 and 28 both have a tubular shape that surrounds the carrier film 2, and these drying sections 26 and 28 heat the dropped resin material by means of a hot air draft. However, the heating part 26 performs pre-heating at a temperature that is slightly lower than the curing temperature of the resin material, while the heating part 28 hardens the resin material by heating said material to its curing temperature.

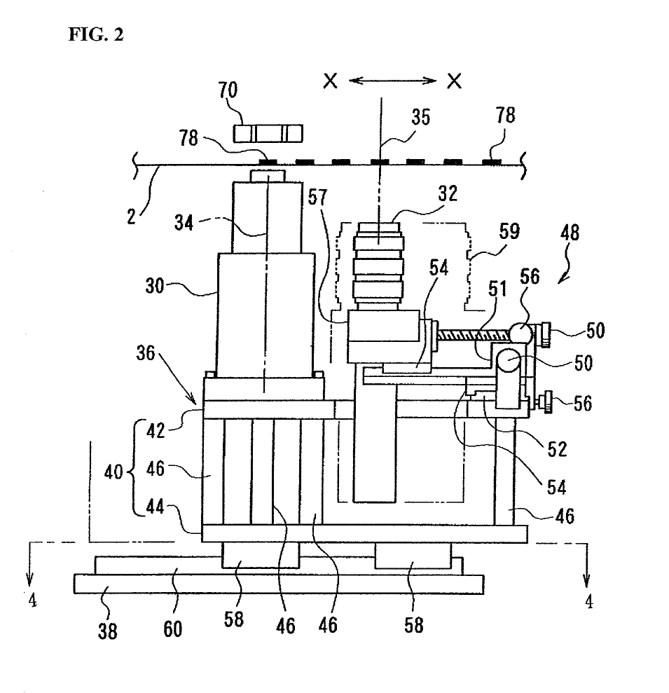

The heater unit 30 and inspection camera 32 are mounted on a moving stand 36. As shown in FIG. 2, the moving stand 36 consists of a fixed part 38 and a movable part 40. The movable part 40 is formed by connecting an upper-surface plate 42 and a bottom-surface plate 44 by means of supporting columns 46. The heater unit 30 is bolted to the upper-surface plate 42, and the inspection camera 32 is set on the upper-surface plate 42 with a position adjustment mechanism 48 interposed.

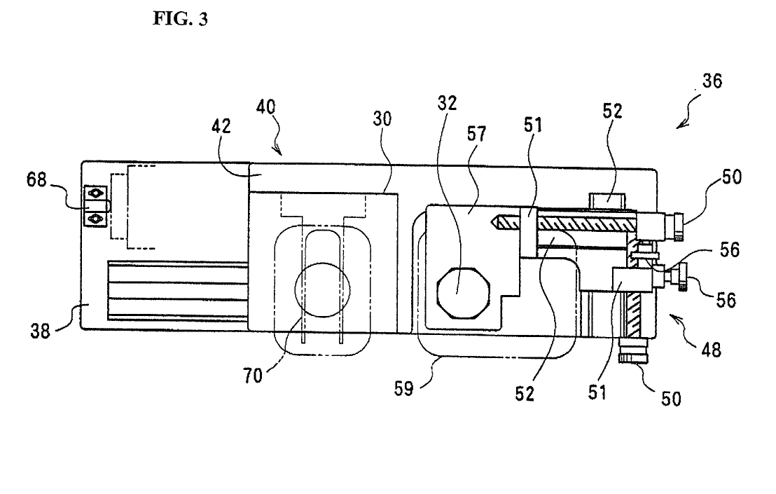

The position adjustment mechanism 48 is used for the manual alteration and setting of the position of the inspection camera 32 in the XY plane. The position adjustment mechanism 48 comprises adjustment screws 50 that adjust the positions in the X and Y directions, a block 51 that is screw-engaged with these adjustment screws 50, a guide rail 52 and slider 54 which are engaged with each other so that the slider 54 is slidable, and a lock screw 56 that fixes the set position. 57 indicates a holder on which the inspection camera 32 is set. The block 51 is moved in the X direction and Y direction (which are the axial directions of the adjustment screws 50) by operating the adjustment screws 50. As a result, the inspection camera 32 moves in the range indicated by the broken line 59 in FIGS. 2 and 3.

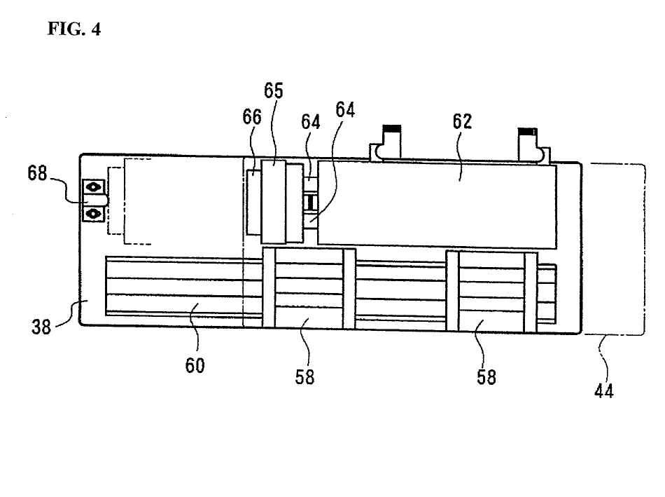

Sliders 58 are fastened to the bottom surface of the bottom-surface plate 44 as shown in FIG. 4. Guide rails 60 are fastened to a fixed part 38 that faces these sliders 58. A reciprocating type hydraulic cylinder 62 is installed parallel to the guide rails 60, and a block 65 and stopper 66 are installed on the tip end of the rod 64 of this hydraulic cylinder 62. The block 65 is fastened to the bottom-surface plate 44 of the movable part 40. 68 indicates an adjustable restrictor which restricts the range of movement of the block 65 and stopper 66. Accordingly, as a result of the protruding and retracting operation of the hydraulic cylinder 62, the movable part 40 of the moving stand 36 is caused to move via the block 65. In this way, the heater unit 30 and inspection camera 32 are caused to move as a unit in the X-X direction (see FIG. 2).

As shown in FIGS. 2 and 3, a bifurcated damper 70 is installed directly above the bonding position 34 so that the damper 70 can be raised and lowered by means of a raising-and-lowering mechanism (not shown in the figures). As a result, the carrier film 2 is pressed against the heater unit 30 in the bonding process.

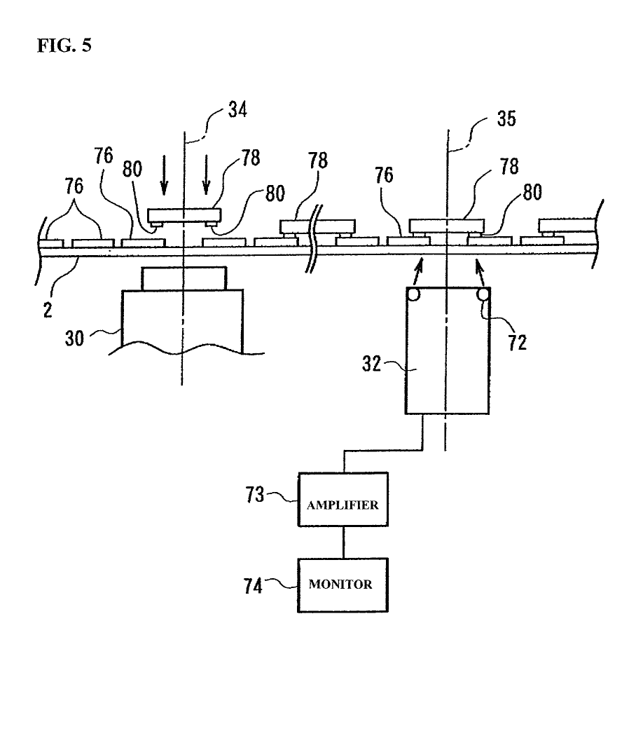

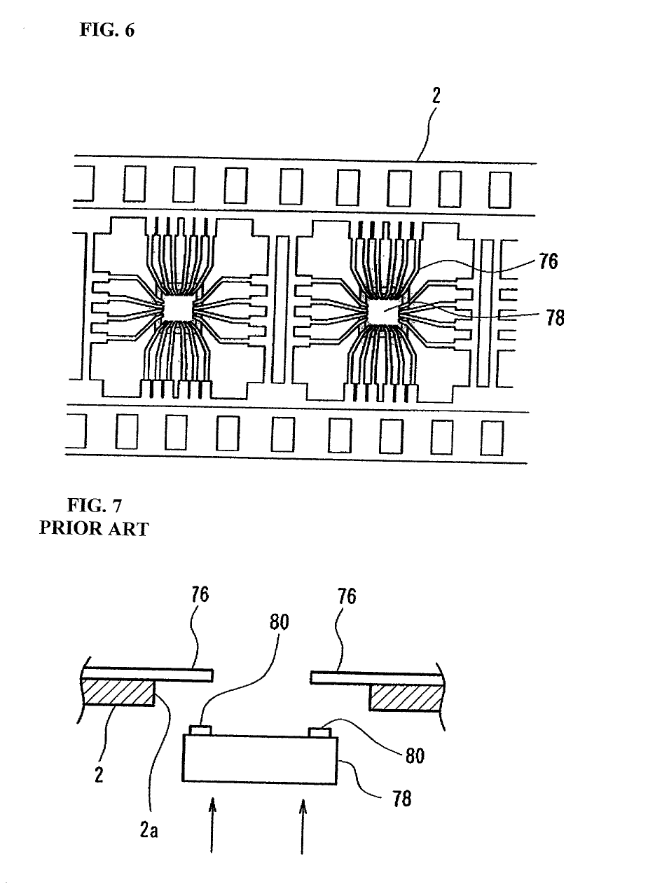

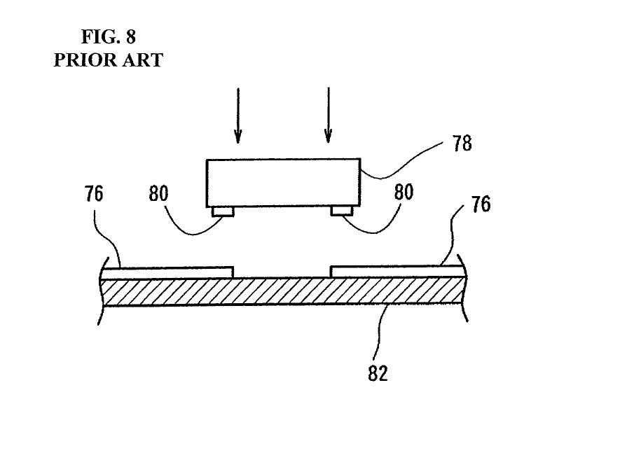

As shown in FIG. 5, a ring-form light source 72 consisting of LEDs is disposed in the upper edge portion of the inspection camera 32. The reason for using a ring-form light source is to avoid halation during imaging. Furthermore, the output side of the inspection camera 32 is connected to a monitor 74 via an amplifier 73, so that a light image of the carrier film 2 can be displayed on this monitor 74.

In the above embodiment, a light-transmitting heat-resistant resin film is used as the carrier film 2. Heat-resistant polyimide films such as products marketed under the trademark Kapton by Du Pont-Toray Co., Ltd. can be used as the carrier film 2. Products marketed under the trademark Upilex by Ube Industries, Ltd. are especially suitable for use as such a resin film. However, any other film which has a heat resistance and mechanical strength that can withstand bonding, and appropriate moisture absorption characteristics, and which consists of a material that transmits visible light, may also be used.

In the electronic part assembly apparatus 1 of the above embodiment, the leads 76 formed on the surface of the carrier film 2 and the bonding pads 80 of the silicon chips 78 are bonded by adhesion using a resin in which a conductive powder is dispersed. In other words, as the initial operation, the heater unit 30 is first positioned in the bonding position 34 as shown in FIG. 2; the carrier film 2 is pressed against the heater unit 30 from above by the damper 70; a silicon chip 78 is placed in the expected position by the transfer arm 31 (see FIG. 1); and then bonding is performed while applying heat and pressure from above by means of the bonding head 12.

Next, the hydraulic cylinder 62 is actuated so that the operating rod of said cylinder 62 is caused to protrude, thus moving the movable part 40 of the moving stand 36 toward the left in the figure. As a result, the inspection camera 32 is positioned in the bonding position 34. Since the image obtained by the inspection camera 32 is displayed on the monitor 74, the worker operates the adjustment screws 50 while viewing this image, and checks for the presence or absence of positional deviations between the leads 76 and the bonding pads 80 by observing the bonded areas around the entire circumference of the silicon chip 78. When any positional deviation exists, the operator operates the operating panel 33 and changes the set value of the offset of the transfer arm 31 (i.e., the positional coordinates in the horizontal direction, i.e., in the X and Y directions). The position of the silicon chip 78 is thus corrected. The above operation is the initial setting operation.

When this initial setting operation is completed, the hydraulic cylinder 62 is next operated so that the operating rod of said cylinder 62 is retracted, thus causing the movable part 40 of the moving stand 36 to move toward the right in the figure. As a result, the heater unit 30 is again positioned in the bonding position 34, and the inspection camera 32 is positioned in the inspection position 35. Afterward, the bonding process is continuously performed by the bonding head 12 and heater unit 30, and the worker makes successive spot checks for positional deviation between the leads 76 and bonding pads 80 while observing the image on the monitor 74 obtained by the inspection camera 32. In cases where there is an abnormality, i.e., a positional deviation between the leads 76 and bonding pads 80 that is outside the permissible range, the operation of the apparatus is stopped, and the operating panel 33 is operated in accordance with the amount of positional deviation in the image on the monitor 74, so that the set value of the offset of the transfer arm 31 is appropriately corrected.

Thus, in the above embodiment, the light transmissivity of the carrier film 2 is utilized, and the conditions of bonding between the leads 76 formed on the carrier film 2 and the bonding pads 80 of the silicon chips 78 are inspected based upon light images of the bonding pads 80 that are transmitted through the carrier film 2. Accordingly, there is no need for a complicated inspection process involving the stripping of bonded silicon chips 78, so that the inspection can be performed with good efficiency.

Furthermore, the conditions of bonding are detected based upon light images of the bonding pads 80 that are transmitted through the band-form carrier film 2 in a state in which a plurality of silicon chips 78 are held in a set on the carrier film 2. Accordingly, detection can be performed continuously without stopping the apparatus, so that the inspection process is made even more efficient.

In addition, the heater unit 30 (constituting the lower member) and the inspection camera 32 are selectively positioned at a location that faces the bonding head 12 (constituting the upper member) by the movement of the movable part 40 of the moving stand 36. Accordingly, an inspection to ascertain whether or not the bonding process has been favorably completed is performed without moving the carrier film 2 by positioning the inspection camera 32 at a position that faces the bonding head 12 after bonding has been performed by the bonding head 12 and heater unit 30. Furthermore, when the heater unit 30 is positioned at a location that faces the bonding head 12, the inspection camera 32 faces silicon chips 78 that have already been subjected to bonding on the carrier film 2. Accordingly, bonding by the bonding head 12 and heater unit 30 and detection by the inspection camera 32 can be continuously performed in parallel by feeding the carrier film 2 from the bonding position 34 where bonding is performed toward the inspection position 35 where detection is performed.

Moreover, a worker inspects for positional deviation between the leads 76 and bonding pads 80 by visual observation of the images on the monitor 74. Instead, however, it is possible to employ a structure in which the output side of the inspection camera 32 is connected to an image processing device, positional deviations between the leads 76 and bonding pads 80 are converted into numerical data by image processing, and an abnormality is judged to have occurred when the amount of positional deviation exceeds a specified permissible value. Moreover, it is also possible to feed back the amount of positional deviation to the amount of offset of the transfer arm 31 so as to automatically correct the positional deviation.

In the above embodiment, the positions of the inspection camera 32 in the X and Y directions are adjusted by the manual operation of adjustment screws 50. However, it is possible to connect respective servo motors to the adjustment screws 50, thus adjusting the positions of the inspection camera 32 in the X and Y directions by manually operate these servo motors. Furthermore, it is also possible to operate such servo motors in accordance with the positioning pitch of the silicon chips 78, thus positioning the inspection camera 32 in an optimal position in accordance with the positioning pitch of the silicon chips 78 in various products.

Moreover, in the above embodiment, a resin material in which a conductive powder is dispersed is used. Instead, various other universally known methods can be used as the bonding method in the present invention, including a method that uses a resin material that does not use a conductive powder, and a method in which the leads 76 and bonding pads 80 are bonded by thermal fusion or a eutectic reaction of both parts without using a resin material itself.

Furthermore, in the above embodiment, the upper member used in the bonding process is the bonding head 12, and the lower member is the heater unit 30. However, the positions of these members may be reversed.

Moreover, the above description of the present invention is made with respect to a die bonder. However, the present invention is not limited to a die bonder. The method and apparatus of the present invention is applicable to various other types of apparatuses used for semiconductor element assembly as well as to other types of electronic part assembly apparatuses utilizing carrier films. Such constructions are in the scope of the present invention.

1. An electronic part inspection method that performs an inspection of a bonding condition between a conductive layer which is formed on an upper surface of a carrier film consisting of a light-transmitting material and bonding pads which are formed on undersurfaces of solid state devices, wherein said inspection is performed based upon light images of said bonding pads that are transmitted through said carrier film.

2. An electronic part inspection method that is comprised of:
a bonding process for bonding bonding pads formed on undersurfaces of a plurality of solid state devices to a conductive layer formed on an upper surface of a band-form carrier film consisting of a light-transmitting material, and
a detection process for detecting conditions of said bonding based upon light images of said bonding pads that are transmitted through said carrier film in a state in which said plurality of solid state devices are held in one set on a surface of said carrier film.

3. An electronic part assembly apparatus comprising:
a bonding device that bonds bonding pads formed on undersurfaces of a plurality of solid state devices to a conductive layer formed on an upper surface of a band-form carrier film consisting of a light-transmitting material, and
a detection device that detects conditions of said bonding based upon light images of said bonding pads that are transmitted through said carrier film in a state in which said plurality of solid state devices are held on a surface of said carrier film.

4. The electronic part assembly apparatus claimed in claim 3, wherein:
said bonding device is comprised of an upper member and a lower member that are respectively provided above and below said carrier film; and
said assembly apparatus is further provided with a moving stand on which said lower member and said detection device are provided, wherein
said lower member and said detection device are selectively positioned, by movement of said moving stand, at a location that faces said upper member, and
when said lower member is positioned at a location that faces said upper member, said detection device faces solid state devices following bonding on said carrier film.
